(19) United States
(12) Patent Application Publication
(10) Pub. No.: US 2026/0114236 A1
(43) Pub. Date: Apr. 23, 2026

(54) APPARATUS FOR MANUFACTURING DISPLAY DEVICE

(71) Applicant: Samsung Display Co., Ltd., Yongin-si (KR)

(72) Inventor: JEONGWON HAN, Yongin-si (KR)

(73) Assignee: Samsung Display Co., Ltd., Yongin-si (KR)

(21) Appl. No.: 19/254,309

(22) Filed: Jun. 30, 2025

(30) Foreign Application Priority Data
Oct. 22, 2024 (KR) 10-2024-0144931

(51) Int. Cl. H01L 21/687; H10K 71/00

(52) U.S. Cl. CPC H10P 72/7624; H10K 71/811

(57) ABSTRACT

Provided is an apparatus for manufacturing a display device. The apparatus for manufacturing a display device includes a chamber having an internal space, a pressure control module that controls an internal pressure of the chamber, and a chuck including a base body arranged in the chamber, an adhesive member to which a substrate is adhered, and an intermediate member having porosity and arranged between the base body and the adhesive member.

### CROSS-REFERENCE TO RELATED APPLICATION(S)

This application claims priority to and benefits of Korean Patent Application No. 10-2024-0144931 under 35 USC § 119, filed Oct. 22, 2024, in the Korean Intellectual Property Office, the entire contents of which are incorporated herein by reference.

### BACKGROUND

### 1. Technical Field

Embodiments of the disclosure relate to an apparatus for manufacturing a display device.

### 2. Description of the Related Art

Mobile electronic devices are being widely used. In addition to small electronic devices, such as mobile phones, tablet PCs have recently been widely used as mobile electronic devices.

Such mobile electronic devices include display devices to provide visual information, such as images or videos, to users to support various functions. Recently, with the miniaturization of other components for operating display devices, the proportion of display devices in electronic devices has been steadily increasing, and structures that can be bent at certain angles from a flat state are being developed.

Physical vapor deposition (PVD) methods, such as vacuum thermal evaporation or electron beam evaporation, may be used as methods for forming thin films on substrates.

To perform these deposition methods, a substrate needs to be fixed to a chuck such that a surface of the substrate, on which a thin film is deposited, faces downward. The types of chucks used for substrate fixation include an electrostatic chuck that fixes a substrate by using an electric field, an adhesive chuck that fixes a substrate by using adhesive force, and a vacuum chuck that fixes a substrate by using vacuum pressure.

The related art described above, which was in possession of inventors for the derivation of the disclosure or acquired during the derivation process of the disclosure, does not necessarily constitute the related art that was publicly disclosed prior to the filing of the disclosure.

### SUMMARY

Embodiments of the disclosure may provide an apparatus for manufacturing a display device, which fixes a substrate during a substrate deposition process.

Problems to be solved by the disclosure are not limited to the above-described problems, and other unmentioned problems and advantages of the disclosure can be understood by the following description and will be more clearly understood by embodiments of the disclosure. In addition, it will be appreciated that the problems and advantages to be solved by the disclosure can be realized by the means and combinations thereof indicated in the claims.

However, embodiments are not limited to those set forth herein. The above and other embodiments will become more apparent to one of ordinary skill in the art to which the disclosure pertains by referencing the detailed description of the disclosure given below.

According to an embodiment of the disclosure, an apparatus for manufacturing a display device includes a chamber having an internal space, a pressure control module that controls an internal pressure of the chamber, and a chuck including a base body arranged in the internal space of the chamber, an adhesive member to which a substrate is adhered, and an intermediate member having porosity and arranged between the base body and the adhesive member.

In an embodiment, the intermediate member may have a plurality of pores through which gas discharged from the adhesive member passes.

In an embodiment, gas discharged from the adhesive member may be discharged to an internal area of the chamber through the plurality of pores of the intermediate member in surface contact with the adhesive member.

In an embodiment, the adhesive member may have a surface in surface contact with the substrate and another surface in surface contact with the intermediate member.

In an embodiment, the base body and the adhesive member may be spaced apart from each other by a selected distance.

In an embodiment, the intermediate member may be adhered to the base body with a first release force, and the adhesive member may be adhered to the intermediate member with a second release force that is smaller than the first release force.

In an embodiment, the substrate may be adhered to the adhesive member with a third release force that is smaller than the second release force.

In an embodiment, a plurality of adhesive members may be disposed on a side of the base body opposite to the substrate, a plurality of intermediate members, each of which is in contact with one of the plurality of adhesive members, may be provided, and the plurality of intermediate members may be spaced apart from each other.

In an embodiment, an area of a cross-section of the intermediate member which is parallel to the substrate may be smaller than an area of a cross-section of the base body which is parallel to the substrate.

In an embodiment, an area of a cross-section of the intermediate member which is parallel to the substrate may be equal to or smaller than an area of a cross-section of the adhesive member which is parallel to the substrate.

According to an embodiment of the disclosure, an apparatus for manufacturing an electronic device, which manufactures an electronic device that outputs image data through a display device including a substrate, includes a chamber having an internal space, a pressure control module that controls an internal pressure of the chamber, and a chuck including a base body arranged in the internal space of the chamber, an adhesive member to which the substrate is adhered, and an intermediate member having porosity and arranged between the base body and the adhesive member.

In an embodiment, the electronic device may be at least one of televisions, notebook computers, monitors, advertisement boards, Internet of things (IoTs), portable electronic apparatuses including mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays (HMDs), instrument panels for automobiles, center fascias for automobiles, or center information displays (CIDs) on a dashboard, room mirror displays of automobiles, and displays of an entertainment system on a backside of front seats in automobiles.

### BRIEF DESCRIPTION OF THE DRAWINGS

The accompanying drawings illustrate embodiments of the disclosure and, together with the detailed description of the disclosure, which will be provided below, serve to provide further understanding of the technical spirit of the disclosure. However, the disclosure is not to be construed as being limited to the drawings in which:

FIG. 1 is a schematic view of an apparatus for manufacturing a display device, according to an embodiment of the disclosure;

FIG. 2 is a schematic perspective view of a chuck unit according to an embodiment of the disclosure;

FIG. 3 is a schematic side view of the chuck unit of FIG. 2;

FIG. 4 is an enlarged schematic view of portion A of FIG. 3;

FIG. 5 is an enlarged schematic view of a chuck unit according to another embodiment of the disclosure;

FIG. 6 is a schematic plan view of a chuck unit according to another embodiment of the disclosure;

FIG. 7 is a schematic side view of the chuck unit of FIG. 6;

FIG. 8 is a schematic plan view of a chuck unit according to another embodiment of the disclosure;

FIG. 9 is a schematic side view of the chuck unit of FIG. 8;

FIG. 10 is a schematic cross-sectional view of a display device manufactured using an apparatus for manufacturing a display device, according to embodiments of the disclosure;

FIG. 11 is a schematic cross-sectional view of a sub-pixel of the display device of FIG. 10; and

FIGS. 12 and 13 are schematic perspective views illustrating application examples of electronic devices.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction X, the axis of the second direction Y, and the axis of the third direction Z are not limited to three axes of a rectangular coordinate system, such as the X, Y, and Z - axes, and may be interpreted in a broader sense. For example, the axis of the first direction X, the axis of the second direction Y, and the axis of the third direction Z may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, example embodiments of the disclosure will be described in detail with reference to the accompanying drawings, in which the like or corresponding elements denote the like reference numerals, and redundant description thereof will be omitted for descriptive convenience.

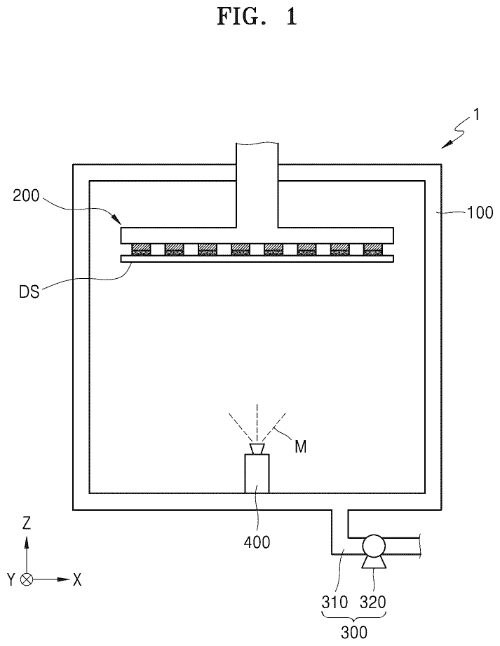

FIG. 1 is a schematic view of an apparatus 1 for manufacturing a display device, according to an embodiment of the disclosure.

Referring to FIG. 1, the apparatus 1 for manufacturing a display device or an apparatus for manufacturing an electronic device, according to an embodiment of the disclosure, may fix the position of a substrate DS in a process of manufacturing the substrate DS, and may include a chamber unit 100, a chuck unit 200, a pressure control module 300, and a deposition unit 400.

The chamber unit 100 may provide a space in which the substrate DS is deposited, and may have a housing shape having a hollow interior.

The interior of the chamber unit 100 may be formed as a vacuum or low-pressure environment. For example, the chamber unit 100 may be in communication with the pressure control module 300, and the pressure control module 300 may discharge gas disposed inside the chamber unit 100 to the outside, thereby forming the internal space of the chamber unit 100 as a vacuum or low-pressure environment.

The chuck unit 200 and the deposition unit 400 may be arranged inside the chamber unit 100. For example, a side (or single side) of the chuck unit 200 to which the substrate DS is attached may be provided opposite to the deposition unit 400, inside the chamber unit 100.

The substrate DS may be attached to the side of the chuck unit 200 arranged inside the chamber unit 100, the pressure control module 300 may discharge gas inside the chamber unit 100 to the outside, thereby forming the internal space of the chamber unit 100 where the substrate DS is positioned, as a vacuum or low-pressure environment, and the deposition unit 400 may perform a process of depositing the substrate DS by ejecting a deposition material toward the substrate DS attached to the side of the chuck unit 200.

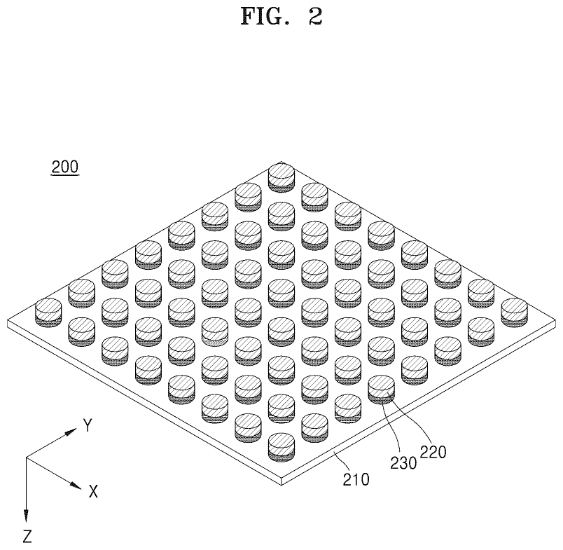

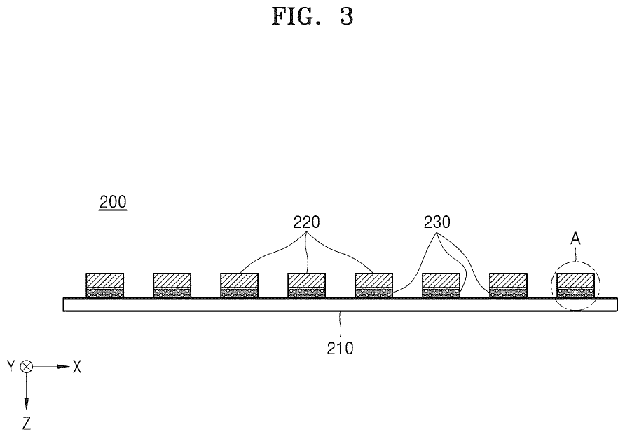

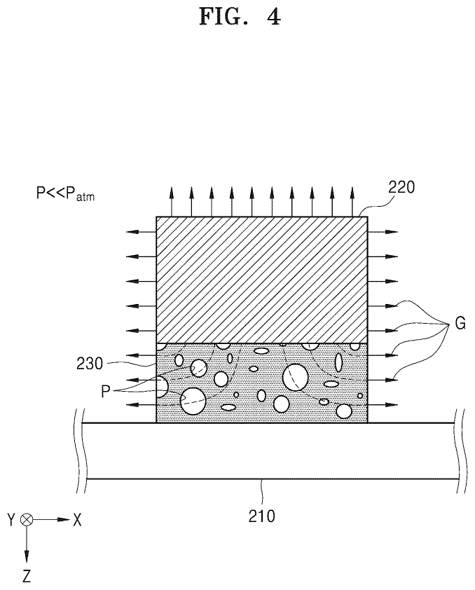

FIG. 2 is a schematic perspective view of the chuck unit 200 according to an embodiment of the disclosure, FIG. 3 is a side view of the chuck unit 200 of FIG. 2, and FIG. 4 is an enlarged schematic view of portion A of FIG. 3.

Referring to FIGS. 2 to 4, the chuck unit 200 according to an embodiment of the disclosure may be a device for fixing the substrate DS, and may include a base body 210, an adhesive member 220, and an intermediate member 230.

The base body 210 may support the adhesive member 220 and the intermediate member 230 and may be position-fixed inside the chamber unit 100.

However, embodiments are not limited thereto, and the base body 210 may be movable or rotatable inside the chamber unit 100 by receiving power from the outside.

The adhesive member 220 may be positioned on a side (or single side) of the base body 210 opposite to the deposition unit 400. For example, the intermediate member 230 may be attached to the side of the base body 210 opposite to the deposition unit 400, and the adhesive member 220 may be position-fixed to the base body 210 via the intermediate member 230.

The substrate DS may be in surface contact with and attached to the adhesive member 220 that is position-fixed to the base body 210. For example, the substrate DS may be attached to a side (or single side) of the adhesive member 220 by adhesive force of the adhesive member 220.

The adhesive member 220 may include a polymer material, such as silicone or polyurethane. However, embodiments are not limited thereto, and the adhesive member 220 may be composed of various materials capable of providing adhesive force to the substrate DS so that the substrate DS may be position-fixed to the adhesive member 220.

The side of the base body 210 opposite to the deposition unit 400 may be flat, and the intermediate member 230 may be attached to a surface of the flat side of the base body 210.

The adhesive member 220 may have a cylindrical shape. For example, the adhesive member 220 may have a cylindrical shape, and the adhesive member 220 and the intermediate member 230 may have the substantially same diameter.

However, embodiments are not limited thereto, and the adhesive member 220 may have a cylindrical shape with a through-hole formed inside or a polygonal pillar shape.

The base body 210 and the adhesive member 220 may be spaced apart from each other by a preset (or selected) distance, and the intermediate member 230 may be arranged between the adhesive member 220 and the base body 210. For example, the intermediate member 230 may be adhered to the side of the base body 210 with a first release force.

The term “first release force” as used herein may be interpreted as the magnitude of adhesive force or bonding force applied between the intermediate member 230 and the base body 210.

The adhesive member 220 may be adhered to the intermediate member 230 with a second release force. For example, the adhesive member 220 may be adhered with a second release force to a side (or single side) of the intermediate member 230 which is opposite to another side of the intermediate member 230 in surface contact with the base body 210, and the first release force may be greater than the second release force.

Thus, in case that repair or replacement of the adhesive member 220 is required due to wear of the adhesive member 220 from repeated use of the adhesive member 220, or other reasons, the adhesive member 220 may be readily separated from the intermediate member 230 while the intermediate member 230 is fixed to the base body 210.

The substrate DS may be adhered to the adhesive member 220 with a third release force, and the third release force may be relatively smaller than the second release force.

For example, the substrate DS may be attached with a third release force to a side (or single side) of the adhesive member 220 opposite to the substrate DS, and the intermediate member 230 may be attached with a second release force to another side of the adhesive member 220 which is opposite to the side.

Thus, during a process of attaching and detaching the substrate DS to and from the adhesive member 220, detachment of the adhesive member 220 from the intermediate member 230 or detachment of the intermediate member 230 from the base body 210 may be prevented.

Referring to FIG. 4, the intermediate member 230 may have pores (P) through which gas G discharged from the adhesive member 220 passes, and the gas G discharged from the adhesive member 220 may be discharged to an internal area of the chamber unit 100 through the pores P of the intermediate member 230 in surface contact with the adhesive member 220.

For example, the pores (P) formed in the intermediate member 230 may be in the form of microtubules, capillaries, microchannels, or the like that connect a side (or single side) of the intermediate member 230 in contact with the adhesive member 220 to an outer circumferential surface of the intermediate member 230 which is exposed to the internal space of the chamber unit 100.

Thus, the gas G discharged from the adhesive member 220 may flow from the contact surface between the adhesive member 220 and the intermediate member 230 to the outer circumferential surface of the intermediate member 230, through the pores P of the intermediate member 230, and be discharged to the internal space of the chamber unit 100.

The adhesive member 220 may include a silicone-based polymer, and in case that a vacuum or low pressure is formed in the internal space of the chamber unit 100, out-gassing may occur from the adhesive member 220, inside the chamber unit 100 which is in a low pressure or vacuum state.

For example, in case that the inside of the chamber unit 100 becomes low pressure or vacuum due to operation of the pressure control module 300, a volatile organic compound included in the adhesive member 220 including a silicone-based polymer may be vaporized and released to the surface of the adhesive member 220.

In case that the adhesive member 220 includes a gas-impermeable material, the out-gassing gas G discharged from the adhesive member 220 forms an air layer between the adhesive member 220 and a supporter, and accordingly, the contact area between the adhesive member 220 and the supporter decreases, which causes the adhesive member 220 to be detached from the supporter.

In the chuck unit 200, the intermediate member 230 including a porous material capable of passing the out-gassing gas G through the intermediate member 230 may be arranged between the base body 210 and the adhesive member 220, and thus the out-gassing gas G discharged from the adhesive member 220 may be discharged to the internal area of the chamber unit 100 through the intermediate member 230 without forming an air layer or bubbles between the base body 210 and the adhesive member 220.

Thus, in case that the internal space of the chamber unit 100 is formed as a vacuum or low pressure environment and the out-gassing gas G of the adhesive member 220 is discharged into a space between the base body 210 and the adhesive member 220, the contact area between the adhesive member 220 and the intermediate member 230 and the contact area between the intermediate member 230 and the base body 210 may be maintained, thereby reducing detachment of the adhesive member 220 from the base body 210.

Adhesive members 220 may be disposed on a side (or single side) of the base body 210 opposite to the substrate DS, and intermediate members 230, each of which is in contact with one of the adhesive members 220, may be provided.

For example, the adhesive members 220 may be spaced apart from each other by a preset (or selected) distance on the side of the base body 210 opposite to the substrate DS, and each of the intermediate members 230 may be adhered to one of the adhesive members 220 spaced apart from each other at equal intervals or evenly spaced apart from each other.

The intermediate member 230 may have a cylindrical shape, and the intermediate member 230 and the adhesive member 220 may have the substantially same diameter. For example, in case that the adhesive member 220 has a cylindrical shape having a preset (or selected) diameter, the intermediate member 230 may have a cylindrical shape, and the intermediate member 230 and the adhesive member 220 may have the substantially same diameter.

A longitudinal central axis of the intermediate member 230 may be coaxial with a longitudinal central axis of the adhesive member 220.

The thickness of the intermediate member 230 may be equal to or relatively smaller than the thickness of the adhesive member 220.

For example, the thickness of the intermediate member 230 may be equal to or relatively smaller than half the thickness of the adhesive member 220.

Thus, the intermediate member 230 may have a thickness only sufficient to provide a discharge path for the out-gassing gas G discharged from the adhesive member 220, thereby reducing deterioration in the structural stability of the adhesive member 220 that occurs due to excessive spacing between the adhesive member 220 and the base body 210.

However, embodiments are not limited thereto, and the thickness of the intermediate member 230 may be equal to or relatively greater than the thickness of the adhesive member 220.

The area of a cross-section of the intermediate member 230 which is parallel to the substrate DS and sectioned by a virtual plane, may be relatively smaller than the area of a cross-section of the base body 210 which is sectioned by the same virtual plane.

The pores P of the intermediate member 230 may have a diameter of about 2 nm to about 100 nm or about 5 nm to about 50 nm.

Thus, the phenomenon where the pores P of the intermediate member 230 may be too small to pass the gas G discharged from the adhesive member 220, through the intermediate member 230, may be prevented, and the phenomenon where the pores P of the intermediate member 230 are so large that the adhesion area or adhesive force between the intermediate member 230 and the base body 210 or the adhesive member 220 decreases may be reduced.

In an embodiment, the pores P of the intermediate member 230 may have various sizes capable of gas passage, for example, a diameter of about 100 nm to about 500 μm.

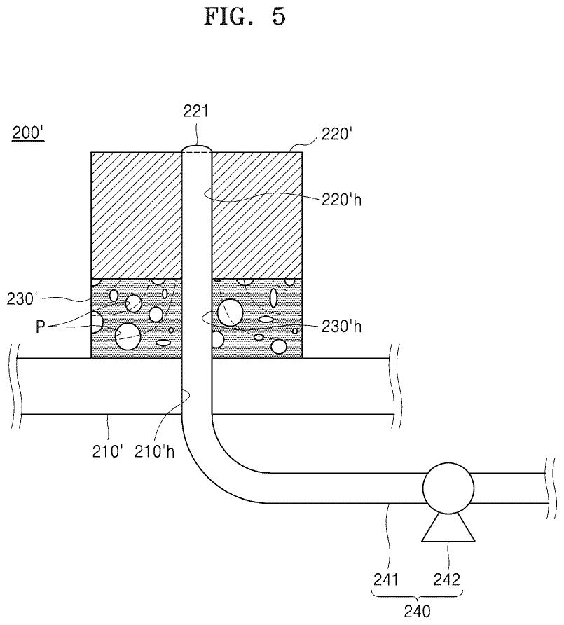

FIG. 5 is an enlarged schematic view of a chuck unit 200′ according to another embodiment of the disclosure.

Referring to FIG. 5, the chuck unit 200′ according to another embodiment of the disclosure has the same structure and operating principle of the chuck unit 200 according to an embodiment of the disclosure, except that the chuck unit 200′ further includes a suction module 240, and a hole portion is formed in a base body 210′, an adhesive member 220′, and an intermediate member 230′, and thus redundant description thereof will be omitted for descriptive convenience.

The chuck unit 200′ may include the base body 210′, the adhesive member 220′, the intermediate member 230′, and the suction module 240.

The suction module 240, which supplies gas to the inside of the adhesive member 220′ to separate the substrate DS from the adhesive member 220′, may include a gas flow path 241 and a gas supply pump 242.

For example, a first hole portion 210′h capable of gas passage may be formed inside the base body 210′, a second hole portion 220′h capable of gas passage may be formed inside the adhesive member 220′, and a third hole portion 230′h may be formed inside the intermediate member 230′.

An elastic member capable of elastic deformation may be arranged on a side (or single side) of the adhesive member 220′ in surface contact with the substrate DS. For example, the elastic member may be in the form of a thin film that covers an opening of the second hole portion 220′h of the adhesive member 220′.

Thus, in case that gas supplied from the suction module 240′ is supplied to the second hole portion 220′h, the elastic member that covers the opening of the second hole portion 220′h may be elastically deformed to become convex outward due to the pressure of the gas supplied to the inside of the second hole portion 220′h.

Therefore, the substrate DS attached to the side of the adhesive member 220′ may be pushed outward by the elastic member, and as a result, may be readily removed from the adhesive member 220′.

The elastic member may include the same material as other areas of the adhesive member 220′, and may be formed integrally (or integral) with the other areas of the adhesive member 220′.

The third hole portion 230′h may be in communication with the first hole portion 210′h and the second hole portion 220′h. For example, one opening of the third hole portion 230′h may be connected to the first hole portion 210′h, and another opening of the third hole portion 230′h which is opposite to the one opening may be connected to the third hole portion 230′h.

The gas flow path 241 may be in the form of a tube which provides the flow path of gas, so that the gas supplied from the gas supply pump 242 may flow into the adhesive member 220′.

In an embodiment, the gas flow path 241 may be arranged inside the chuck unit 200′ by sequentially penetrating the first hole portion 210′h, the third hole portion 230′h, and the second hole portion 220′h.

Thus, external gas supplied from the gas supply pump 242 may flow to the inside of the adhesive member 220′ through the gas flow path 241, and accordingly, the elastic member may become convex and inflated outward. Accordingly, the substrate DS attached to the adhesive member 220′ may be readily detached from the adhesive member 220′ by elastic deformation of the elastic member.

For example, by simultaneous penetration of the gas flow path 241 through the base body 210′, the intermediate member 230′, and the adhesive member 220′, the adhesive member 220′ and the intermediate member 230′ may be more firmly fixed to the base body 210′.

The gas flow path 241 may extend along at least one of the longitudinal central axis of the intermediate member 230′ and the longitudinal central axis of the adhesive member 220′.

In an embodiment, the gas flow path 241 may sequentially penetrate the first hole portion 210′h and the third hole portion 230′h and be spaced apart from the adhesive member 220′.

For example, the gas flow path 241 may extend only to the adhesion surface between the adhesive member 220′ and the intermediate member 230′ and communicate with the second hole portion 220′h.

Thus, the gas flow path 241 may be arranged on the inside of the intermediate member 230′ including a gas-permeable material to prevent gas supplied from the gas supply pump 242, from being discharged to the outside through the intermediate member 230′, and by supplying gas to the second hole portion 220′h of the adhesive member 220′ including a gas-impermeable material, pressure of the gas supplied from the gas supply pump 242 may be effectively transferred to the elastic member.

For example, because the gas flow path 241 is arranged only up to the contact surface between the adhesive member 220′ and the intermediate member 230′ and is spaced apart from the internal area of the adhesive member 220′, a user may readily remove and replace the adhesive member 220′, which is a consumable part, from the intermediate member 230′.

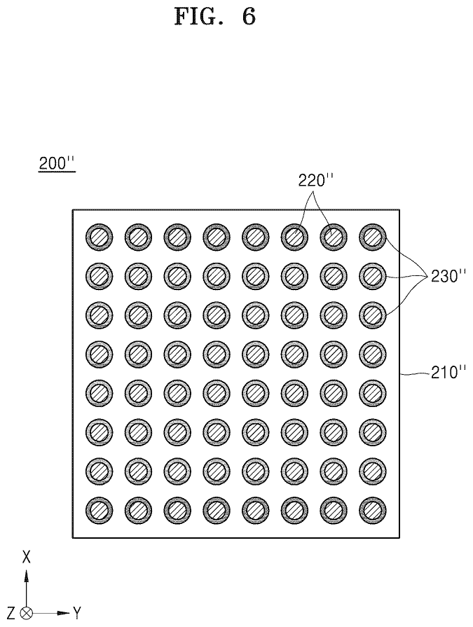

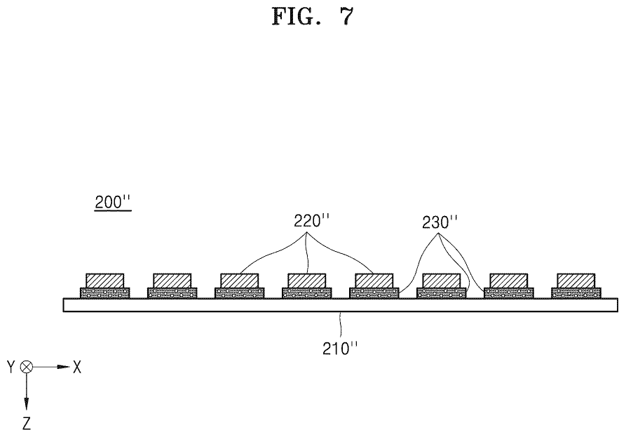

FIG. 6 is a schematic plan view of a chuck unit 200″ according to another embodiment of the disclosure, and FIG. 7 is a schematic side view of the chuck unit 200″ of FIG. 6.

The chuck unit 200″ according to another embodiment of the disclosure has the same structure and operating principle as the chuck unit 200 according to an embodiment of the disclosure, except that the diameter of an adhesive member 220″ is smaller than that of an intermediate member 230″, and thus redundant description thereof will be omitted for descriptive convenience.

Referring to FIGS. 6 and 7, in the chuck unit 200″ according to another embodiment of the disclosure, the diameter of the intermediate member 230″ may be relatively larger than that of the adhesive member 220″.

For example, the adhesive member 220″ may have a cylindrical shape with a first diameter, and the intermediate member 230″ may have a cylindrical shape with a second diameter larger than the first diameter.

For example, the longitudinal central axis of the adhesive member 220″ and the longitudinal central axis of the intermediate member 230″ may be coaxial, and the thickness of the adhesive member 220″ may be relatively greater than that of the intermediate member 230″.

Thus, the contact surface between the intermediate member 230″ and the base body 210″ may be relatively larger than the contact surface between the adhesive member 220″ and the intermediate member 230″, and therefore, the intermediate member 230″ may be firmly fixed to the base body 210″.

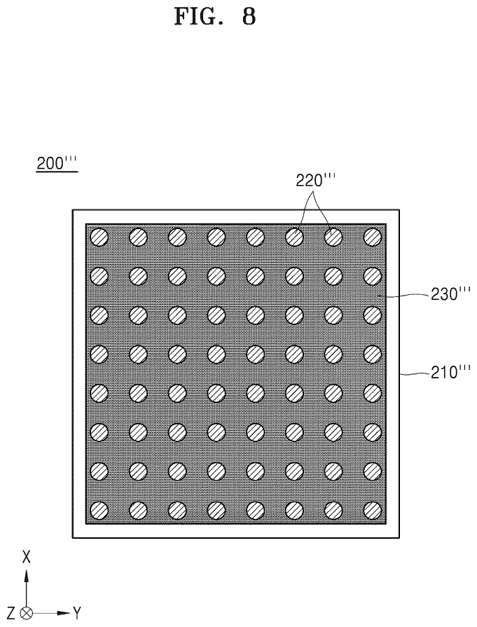

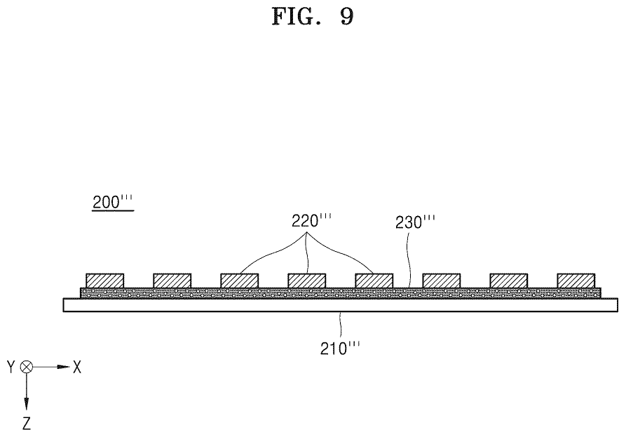

FIG. 8 is a schematic plan view of a chuck unit 200′″ according to another embodiment of the disclosure, and FIG. 9 is a schematic side view of the chuck unit 200′″ of FIG. 8.

The chuck unit 200′″ according to another embodiment of the disclosure has the same structure and operating principle as the chuck unit 200 according to an embodiment of the disclosure, except that adhesive members 220′″ are attached to an intermediate member 230′″, and thus redundant description thereof will be omitted for descriptive convenience.

Referring to FIGS. 8 and 9, in the chuck unit 200′″ according to another embodiment of the disclosure, the adhesive members 220′″ may be attached to the intermediate member 230′″.

For example, the intermediate member 230′″ may have a plate shape with a side length relatively larger than the diameters of the adhesive members 220′″, and the adhesive members 220′″ may be spaced apart from each other by a preset (or selected) distance and attached to the intermediate member 230′″ having a plate shape.

For example, the thickness of the adhesive member 220′″ may be relatively greater than that of the intermediate member 230′″.

Thus, the contact surface between the intermediate member 230′″ and the base body 210′″ may be relatively larger than the contact surface between the adhesive member 220′″ and the intermediate member 230′″, and therefore, the intermediate member 230′″ may be firmly fixed to the base body 210′″.

Referring back to FIG. 1, the pressure control module 300 according to an embodiment of the disclosure, which controls the internal pressure of the chamber unit 100, may include a pressure control passage 310 and a pressure control pump 320.

The pressure control passage 310 may perform communication (e.g., fluid connection) between the internal space of the chamber unit 100 and the pressure control pump 320, and may provide a discharge path for gas disposed in the internal space of the chamber unit 100.

The pressure control pump 320 may include various devices capable of controlling the internal pressure of the chamber unit 100. For example, the pressure control pump 320 may include a rotary vane pump, a turbo molecular pump, a scroll pump, a diffusion pump, a cryo pump, an ion pump, or the like.

The deposition unit 400 may be arranged inside the chamber unit 100 and include at least one nozzle that ejects a deposition material.

The deposition unit 400 may eject a deposition material toward the substrate DS fixed to the chuck unit 200.

The deposition unit 400 may evaporate at least one deposition material selected from an organic material, an inorganic material, and a conductive material, toward the chuck unit 200. For example, the deposition unit 400 may deposit a deposition material on the substrate DS by evaporating the deposition material through heating to a high temperature.

In an embodiment, the deposition unit 400 may include a heater for heating a deposition material.

The nozzle may be connected to the deposition unit 400 and provide a deposition material vaporized or sublimated in the deposition unit 400, to the outside.

For example, the nozzles may be spaced apart from each other and be in dot nozzle form in which nozzles are arranged in a dot shape. However, embodiments are not limited thereto and the nozzle may be in line nozzle form that ejects a deposition material onto a certain area.

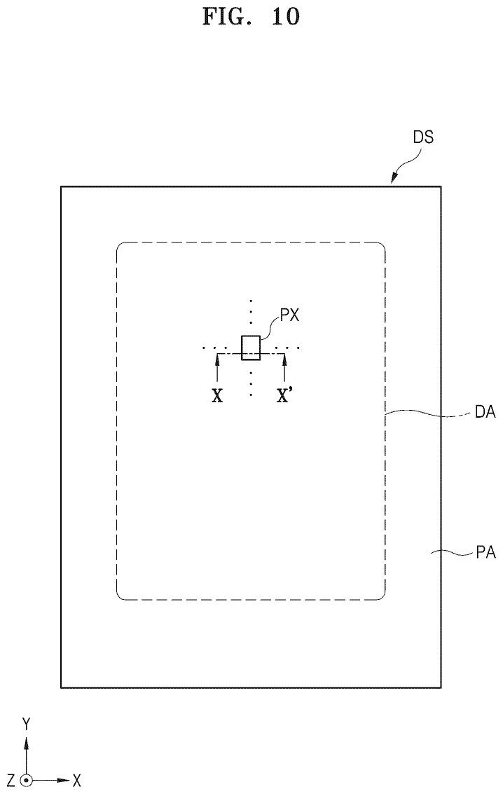

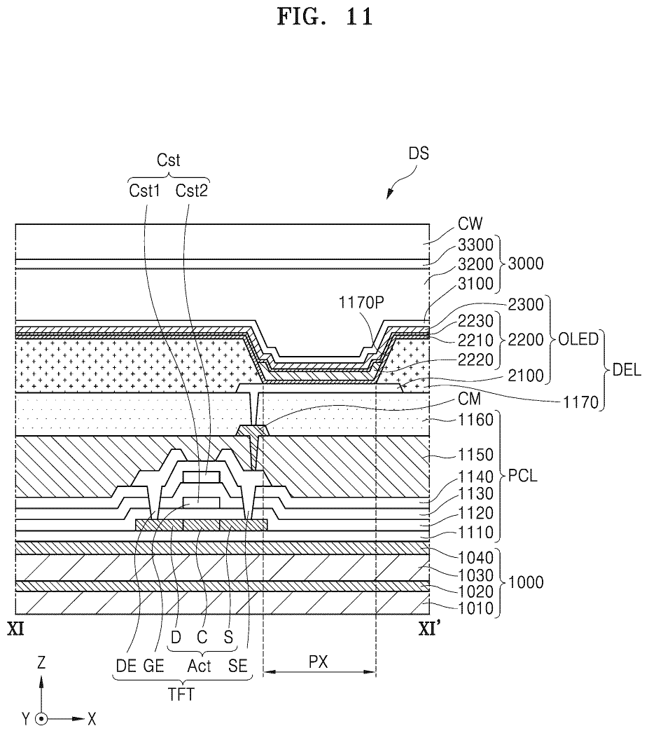

FIG. 10 is a schematic cross-sectional view of a display device manufactured using an apparatus for manufacturing a display device, according to embodiments of the disclosure. FIG. 11 is a schematic cross-sectional view of a sub-pixel of the display device of FIG. 10.

Referring to FIG. 10, a display device DS manufactured according to an embodiment of the disclosure may include a display area DA and a peripheral area PA positioned outside the display area DA. The display device DS may provide an image through an array of pixels PX arranged two-dimensionally in the display area DA.

The peripheral area PA, which is an area that does not provide an image, may entirely or partially surround the display area DA. A driver for providing electrical signals or power to pixel circuits, each of which corresponds to one of the pixels PX, and the like may be arranged in the peripheral area PA. Pads, which are areas where electronic components, a printed circuit board, or the like may be electrically connected, may be arranged in the peripheral area PA.

Hereinafter, a case where the display device DS includes an organic light-emitting diode (OLED) as a light-emitting element will be described, but the display device DS of the disclosure is not limited thereto.

In other embodiments, the display device DS may be a light-emitting display device including an inorganic light-emitting diode, for example, an inorganic light-emitting display device. The inorganic light-emitting diode may include a PN diode including inorganic semiconductor-based materials.

In case that a forward voltage is applied to a PN junction diode, holes and electrons are injected, and energy generated by recombination of the holes and the electrons may be converted into light energy to emit light of a certain color. The aforementioned inorganic light-emitting diode may have a width of several to several hundred micrometers, and in some embodiments, the inorganic light-emitting diode may be referred to as a micro LED.

In another embodiment, the display device DS may be a quantum dot light-emitting display device.

In some embodiments, the display device DS may be used as a display screen in various products, including portable electronic devices, such as mobile phones, smart phones, tablet personal computers (PCs), mobile communication terminals, electronic notebooks, electronic books, portable multimedia players (PMPs), navigation devices, and ultramobile PCs (UMPCs), as well as televisions, laptops, monitors, billboards, and internet of things (IOT) devices.

For example, the display device DS according to an embodiment may be used in wearable devices, such as smart watches, watch phones, glasses-type displays, and head mounted displays (HMDs).

For example, the display device DS according to an embodiment may be used as an instrument panel of a vehicle, a center information display (CID) disposed in the center fascia or dashboard of a vehicle, a room mirror display that replaces the side mirrors of a vehicle, and a display screen arranged on the back of front seats for rear seat entertainment of a vehicle.

Referring to FIG. 11, the display device DS may include a stacked structure of a substrate 1000, a pixel circuit layer PCL, a display element layer DEL, and an encapsulation layer 3000.

The substrate 1000 may have a multilayer structure including a base layer including a polymer resin and an inorganic layer. For example, the substrate 1000 may include a base layer including a polymer resin and a barrier layer as an inorganic insulating layer.

For example, the substrate 1000 may include a first base layer 1010, a first barrier layer 1020, a second base layer 1030, and a second barrier layer 1040, which are sequentially stacked. The first base layer 1010 and the second base layer 1030 may include polyimide (PI), polyethersulfone (PES), polyarylate, polyetherimide (PEI), polyethyelenene napthalate (PEN), polyethyeleneterepthalate (PET), polyphenylene sulfide (PPS), polycarbonate (PC), cellulose triacetate (TAC), and/or cellulose acetate propionate (CAP).

The first barrier layer 1020 and the second barrier layer 1040 may include an inorganic insulating material, such as silicon oxide, silicon oxynitride, and/or silicon nitride. The substrate 1000 may have flexibility.

The pixel circuit layer PCL may be disposed on the substrate 1000. FIG. 11 illustrates a case where the pixel circuit layer PCL includes a thin film transistor TFT, and a buffer layer 1110, a first gate insulating layer 1120, a second gate insulating layer 1130, an interlayer insulating layer 1140, a first planarization insulating layer 1150, and a second planarization insulating layer 1160, which are disposed below and/or above components of the thin film transistor TFT.

The buffer layer 1110 may reduce or block permeation of foreign substances, moisture, or external air from a lower portion of the substrate 1000, and may provide a planar surface on the substrate 1000.

The buffer layer 1110 may include an inorganic insulating material, such as silicon oxide, silicon oxynitride, or silicon nitride, and may have a single-layered structure or a multilayer structure, which include the aforementioned material(s).

The thin film transistor TFT disposed on the buffer layer 1110 may include a semiconductor layer Act, and the semiconductor layer Act may include polysilicon.

For example, the semiconductor layer Act may include amorphous silicon, an oxide semiconductor, an organic semiconductor, or the like.

The semiconductor layer Act may include a channel region C, and a drain region D and a source region S which are arranged respectively on opposite sides of the channel region C. A gate electrode GE may overlap the channel region C.

The gate electrode GE may include a low-resistance metal material. The gate electrode GE may include a conductive material containing molybdenum (Mo), aluminum (Al), copper (Cu), titanium (Ti), or the like, and may be formed as a multilayer or single layer including these materials.

The first gate insulating layer 1120 between the semiconductor layer Act and the gate electrode GE may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂).

The second gate insulating layer 1130 may be provided to cover the gate electrode GE. Similar to the first gate insulating layer 1120, the second gate insulating layer 1130 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂).

An upper electrode Cst2 of a storage capacitor Cst may be arranged on the second gate insulating layer 1130. The upper electrode Cst2 may overlap the gate electrode GE arranged below the upper electrode Cst2. For example, the gate electrode GE and the upper electrode Cst2 that overlap the second gate insulating layer 1130 present therebetween may form the storage capacitor Cst. For example, the gate electrode GE may function as a lower electrode Cst1 of the storage capacitor Cst.

As such, the storage capacitor Cst and the thin film transistor TFT may overlap each other. In some embodiments, the storage capacitor Cst may not overlap the thin film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be formed as a single layer or multilayer including the aforementioned material(s).

The interlayer insulating layer 1140 may cover the upper electrode Cst2. The interlayer insulating layer 1140 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), zinc oxide (ZnO_{X}), or the like. Zinc oxide (ZnO_{X}) may be zinc oxide (ZnO) and/or zinc peroxide (ZnO₂). The interlayer insulating layer 1140 may be formed as a single layer or multilayer including the aforementioned inorganic insulating material(s).

The drain electrode DE and the source electrode SE may each be positioned on the interlayer insulating layer 1140. The drain electrode DE and the source electrode SE may be connected to the drain region D and the source region S, respectively, through contact holes formed in the insulating layers arranged below the drain electrode DE and the source electrode SE. The drain electrode DE and source electrode SE may include a material having good conductivity. The drain electrode DE and the source electrode SE may include a conductive material including molybdenum (Mo), aluminum (Al), copper (Cu), titanium (Ti), or the like, and may be formed as a multilayer or single layer including the aforementioned material(s). In an embodiment, the drain electrode DE and the source electrode SE may have a multilayer structure of Ti/Al/Ti.

The first planarization insulating layer 1150 may cover the drain electrode DE and the source electrode SE. The first planarization insulating layer 1150 may include organic insulating materials, such as a general-purpose polymer (e.g., polymethylmethacrylate (PMMA) or polystyrene (PS)), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and a blend thereof.

The second planarization insulating layer 1160 may be disposed on the first planarization insulating layer 1150. The second planarization insulating layer 1160 and the first planarization insulating layer 1150 may include the same material, and the second planarization insulating layer 1160 may include organic insulating materials, such as a general-purpose polymer (e.g., PMMA or PS), a polymer derivative having a phenolic group, an acrylic polymer, an imide-based polymer, an aryl ether-based polymer, an amide-based polymer, a fluorinated polymer, a p-xylene-based polymer, a vinyl alcohol-based polymer, and a blend thereof.

The display element layer DEL may be disposed on the pixel circuit layer PCL having the above-described structure. The display element layer DEL may include an organic light-emitting diode OLED as a display element (e.g., a light-emitting element), and the organic light-emitting diode OLED may include a stacked structure of a pixel electrode 2100, an intermediate layer 2200, and a common electrode 2300. The organic light-emitting diode OLED may emit, for example, red light, green light, or blue light, or may emit red light, green light, blue light, or white light. The organic light-emitting diode OLED may emit light through a light-emitting area, and the light-emitting area may be defined as a pixel PX.

The pixel electrode 2100 of the organic light-emitting diode OLED may be electrically connected to the thin film transistor TFT through contact holes formed in the second planarization insulating layer 1160 and the first planarization insulating layer 1150 and a contact metal CM arranged on the first planarization insulating layer 1150.

The pixel electrode 2100 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In other embodiments, the pixel electrode 2100 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In other embodiments, the pixel electrode 2100 may further include a film including ITO, IZO, ZnO, or In₂O₃ above/below the aforementioned reflective film.

A pixel defining layer 1170 having an opening 1170P that exposes a central portion of the pixel electrode 2100 may be arranged on the pixel electrode 2100. The pixel defining layer 1170 may include an organic insulating material and/or an inorganic insulating material. The opening 1170P may define the light-emitting area of light emitted from the organic light-emitting diode OLED. For example, the size/width of the opening 1170P may correspond to the size/width of the light-emitting area. Therefore, the size and/or width of the pixel PX may depend on the size and/or width of the opening 1170P in the corresponding pixel defining layer 1170.

The intermediate layer 2200 may include an emission layer 2220 arranged to correspond to the pixel electrode 2100. The emission layer 2220 may include polymeric or small-molecular organic materials that emit light of a certain color. For example, the emission layer 2220 may include an inorganic light-emitting material or quantum dots.

In an embodiment, the intermediate layer 2200 may include a first functional layer 2210 and a second functional layer 2230 respectively arranged below and above the emission layer 2220. The first functional layer 2210 may include, for example, a hole transport layer (HTL) or a HTL and a hole injection layer (HIL). The second functional layer 2230, which is a component arranged on the emission layer 2220, may include an electron transport layer (ETL) and/or an electron injection layer (EIL). The first functional layer 2210 and/or the second functional layer 2230 may be common layers formed to cover (e.g., entirely cover) the substrate 1000, similar to the common electrode 2300, which will be described below.

The common electrode 2300 may be arranged on the pixel electrode 2100 and overlap the pixel electrode 2100. The common electrode 2300 may include a conductive material with a low work function. For example, the common electrode 2300 may include a semi-transparent or a transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. For example, the common electrode 2300 may further include a layer including ITO, IZO, ZnO, or In₂O₃ on the semi-transparent or a transparent layer including the aforementioned material. The common electrode 2300 may be integrally formed (or integral) to cover (e.g., entirely cover) the substrate 1000.

The encapsulation layer 3000 may be arranged on the display element layer DEL and cover the display element layer DEL. The encapsulation layer 3000 may include at least one inorganic encapsulation layer and at least one organic encapsulation layer. In an embodiment, a case where the encapsulation layer 3000 includes a first inorganic encapsulation layer 3100, an organic encapsulation layer 3200, and a second inorganic encapsulation layer 3300, which are sequentially stacked, is illustrated in FIG. 11.

The first inorganic encapsulation layer 3100 and the second inorganic encapsulation layer 3300 may include at least one inorganic material selected from aluminum oxide, titanium oxide, tantalum oxide, hafnium oxide, zinc oxide, silicon oxide, silicon nitride, and silicon oxynitride. The organic encapsulation layer 3200 may include a polymer-based material. Non-limiting examples of the polymer-based material may include acrylic resins, epoxy resins, polyimides, and polyethylene. In an embodiment, the organic encapsulation layer 3200 may include acrylate. The organic encapsulation layer 3200 may be formed by curing a monomer or coating a polymer. The organic encapsulation layer 3200 may have transparency.

For example, a touch sensor layer may be arranged on the encapsulation layer 3000, and an optical functional layer may be arranged on the touch sensor layer. The touch sensor layer may acquire coordinate information based on external input, for example, a touch event. The optical functional layer may reduce reflectance of light (e.g., external light) incident on a display device from the outside, and/or may improve color purity of light emitted from the display device. In an embodiment, the optical functional layer may include a retarder and/or a polarizer. The retarder may be a film type or a liquid crystal coating type, and may include a λ/2 retarder and/or a λ/4 retarder. The polarizer may also be a film type or a liquid crystal coating type. The film type may include a stretchable synthetic resin film, and the liquid crystal coating type may include liquid crystals aligned in a certain arrangement. The retarder and the polarizer may further include a protective film.

An adhesive member may be arranged between the touch sensor layer and the optical function layer. The adhesive member may be employed from those generally known in the art, without limitation. The adhesive member may be a pressure-sensitive adhesive (PSA).

A cover window CW may be arranged on the encapsulation layer 3000, and a touch sensor layer and/or an optical functional layer may be arranged on the cover window CW. The cover window CW may include at least one of glass, sapphire, and plastic. The cover window CW may be, for example, ultra-thin tempered glass or colorless polyimide. In an embodiment, the cover window CW may have a structure in which a flexible polymer layer is arranged on a side (or single side) of a glass substrate, or may consist only of a polymer layer.

The cover window CW may be attached by an adhesive member. The adhesive member may be a liquid optically clear resin (OCR) or an optically clear adhesive (OCA) film and/or a PSA.

For example, the electronic device may output various types of information, such as video information and audio information, through the display device in an operating system. For example, in case that a processor executes an application stored in memory, the electronic device may provide application information to a user through the display device.

The electronic device may communicate with an external device via a network (e.g., a short-range wireless communication network or a long-range wireless communication network).

In an embodiment, the electronic device may include a processor, a memory, an input module, a display device DS, a power module, a built-in module, and an external module.

In an embodiment, the electronic device may omit at least one of the components described above, or may further include one or more other components. In an embodiment, some of the components described above (e.g., a sensor module, an antenna module, or an audio output module) may be integrated into another component (e.g., the display device DS).

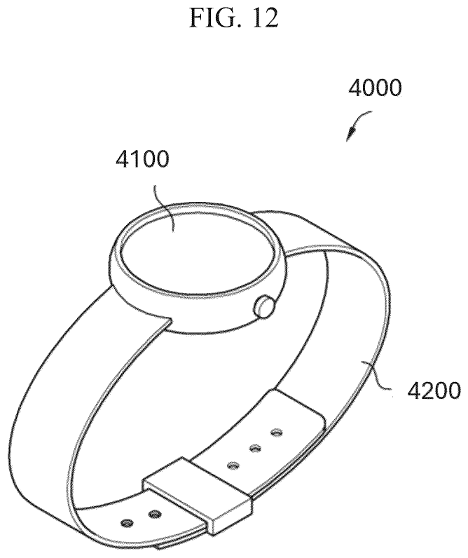

Referring to FIG. 12, the electronic device may be applied to a smart watch 4000 including a display part 4100 and a strap part 4200.

The smart watch 4000 may be a wearable electronic device. For example, the smart watch 4000 may have a structure in which the strap part 4200 is mounted on a wrist of a user. The electronic device may be applied to the display part 4100, so that image data including time information can be provided to the user.

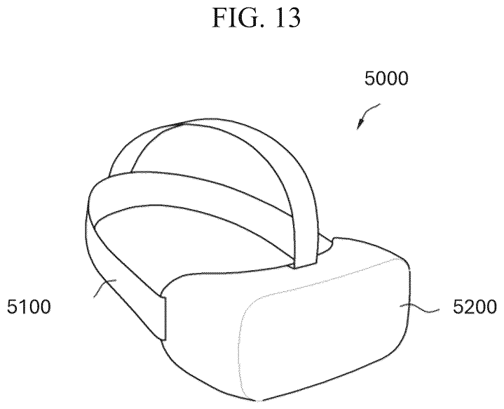

Referring to FIG. 13, the electronic device may be applied to a head mounted display device 5000.

The head mounted display device 5000 may be a wearable electronic device which can be worn on the head of a user. For example, the head mounted display device 5000 may be a wearable device for virtual reality (VR) or mixed reality (MR). The head mounted display device 5000 may include a head mounted band 5100 and a display accommodating case 5200. The head mounted band 5100 may be connected to the display accommodating case 5200. The head mounted band 5100 may include a horizontal band and/or a vertical band, used to fix the head mounted display device 5000 to the head of the user. The horizontal band may be configured to surround a side portion of the head of the user, and the vertical band may be configured to surround an upper portion of the head of the user. However, embodiments are not limited thereto. For example, the head mounted band 5100 may be implemented in the form of a glasses frame, a helmet or the like within the spirit and the scope of the disclosure. For example, the electronic device may be at least one of televisions, notebook computers, monitors, advertisement boards, Internet of things (IoTs), portable electronic apparatuses including mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays (HMDs), instrument panels for automobiles, center fascias for automobiles, or center information displays (CIDs) on a dashboard, room mirror displays of automobiles, and displays of an entertainment system on a backside of front seats in automobiles.

The embodiments described above may each independently be implemented, but the structure of each of the embodiments may be applied in combination to other embodiments.

Although the disclosure has been described with reference to the embodiments shown in the drawings, these embodiments are provided for illustrative purposes only, and it will be understood by those of ordinary skill in the art that various modifications and other equivalent embodiments can be made therefrom. Therefore, the true technical scope of the disclosure should be defined by the technical idea of the appended claims.

The particular implementations described in embodiments are embodiments and are not intended to limit the scope of the embodiments in any way. No component is essential to the practice of the disclosure unless the element is specifically described as “essential,” “critical,” or the like.

The use of the term “the” and similar referents in embodiments of the specification (especially in the claims) should be construed to cover both the singular and the plural. in cases where a range is described in embodiments, it shall be construed as including inventions applying individual values belonging to said range (unless there is a statement to the contrary), as if each individual value constituting said range were described in detail in the specification. Finally, the steps of methods according to embodiments can be performed in any suitable order unless otherwise indicated herein or otherwise clearly contradicted by context. The embodiments are not necessarily limited to the order in which the above steps are described. The use of any and all examples or exemplary languages provided in embodiments is merely intended to describe embodiments in detail, and is not intended to limit the scope of the embodiments, unless otherwise defined by the claims. Moreover, it will be understood by those of ordinary skill in the art that various modifications, combinations, and changes may be made within the scope of the appended claims or equivalents thereto, depending on design conditions and factors.

An apparatus for manufacturing a display device, according to embodiments of the disclosure, includes an intermediate member positioned between a base body and an adhesive member and including a porous material through which gas discharged from the adhesive member passes, thereby minimizing the formation of a gas layer between the base body and the adhesive member. Therefore, the adhesive member is firmly fixed to the base body.

However, the effects obtainable through the disclosure are not limited to the effects described above, and other unmentioned technical effects will be clearly understood by those of ordinary skills in the art from the description of the disclosure set forth below.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. An apparatus for manufacturing a display device, the apparatus comprising:
a chamber having an internal space;
a pressure control module that controls an internal pressure of the chamber; and
a chuck including:
a base body arranged in the internal space of the chamber,
an adhesive member to which a substrate is adhered, and
an intermediate member having porosity and arranged between the base body and the adhesive member.

2. The apparatus of claim 1, wherein the intermediate member has a plurality of pores through which gas discharged from the adhesive member passes.

3. The apparatus of claim 2, wherein the gas discharged from the adhesive member is discharged to an internal area of the chamber through the plurality of pores of the intermediate member in surface contact with the adhesive member.

4. The apparatus of claim 1, wherein the adhesive member has a surface in surface contact with the substrate and another surface in surface contact with the intermediate member.

5. The apparatus of claim 1, wherein the base body and the adhesive member are spaced apart from each other by a selected distance.

6. The apparatus of claim 5, wherein
the intermediate member is adhered to the base body with a first release force, and
the adhesive member is adhered to the intermediate member with a second release force that is smaller than the first release force.

7. The apparatus of claim 6, wherein the substrate is adhered to the adhesive member with a third release force that is smaller than the second release force.

8. The apparatus of claim 5, wherein
a plurality of the adhesive members are arranged on a side of the base body opposite to the substrate, and
a plurality of the intermediate members, each of which is in contact with one of the plurality of adhesive members, are provided, the plurality of the intermediate members being spaced apart from each other.

9. The apparatus of claim 1, wherein an area of a cross-section of the intermediate member which is parallel to the substrate is smaller than an area of a cross-section of the base body which is parallel to the substrate.

10. The apparatus of claim 9, wherein the area of a cross-section of the intermediate member which is parallel to the substrate is equal to or smaller than the area of a cross-section of the adhesive member which is parallel to the substrate.

11. An apparatus for manufacturing an electronic device, which manufactures an electronic device that outputs image data through a display device including a substrate, the apparatus comprising:
a chamber having an internal space;
a pressure control module that controls an internal pressure of the chamber; and
a chuck including:
a base body arranged in the internal space of the chamber,
an adhesive member to which the substrate is adhered, and
an intermediate member having porosity and arranged between the base body and the adhesive member.

12. The electronic device of claim 11, wherein the electronic device is at least one of televisions, notebook computers, monitors, advertisement boards, Internet of things (IoTs), portable electronic apparatuses including mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays (HMDs), instrument panels for automobiles, center fascias for automobiles, or center information displays (CIDs) on a dashboard, room mirror displays of automobiles, and displays of an entertainment system on a backside of front seats in automobiles.
